(19) United States
(12) Patent Application Publication
(10) Pub. No.: US 2012/0147592 A1
(43) Pub. Date: Jun. 14, 2012

(54) ELECTRONIC PACKAGE, LIGHTING DEVICE, AND DISPLAY DEVICE

(75) Inventor: Kenji Takase, Osaka-shi (JP)

(73) Assignee: Sharp Kabushiki Kaisha, Osaka-shi, Osaka (JP)

(21) Appl. No.: 13/391,002

(22) PCT Filed: Apr. 22, 2010
(86) PCT No.: PCT/JP2010/057111

§ 371 Date: Feb. 17, 2012

(30) Foreign Application Priority Data
Sep. 4, 2009 (JP) 2009-204495

(51) Int. Cl. G09F 13/04; H05K 7/14; F21V 7/00

(52) U.S. Cl. 362/97.1; 362/296.01; 361/759

(57) ABSTRACT

Provided is an electronic package (PG) which is made without using screws or double-sided adhesive tapes, so cost can be reduced and the manufacturing process can be made simpler. This is done by configuring the electronic package (PG) so that a backlight chassis (10) thereof includes anchoring claws (11) for fixing a mounted substrate (21) onto itself. A lighting device (backlight unit (49)) and a displaying device (liquid crystal display device (69)) are provided with this electronic package (PG).

### TECHNICAL FIELD

The present invention relates to an electronic package as a part of an electronic device, and more particularly to an electronic package that includes a chassis and a mounting board fitted to the chassis. The invention also relates to, as examples of electronic devices, illuminating devices and display devices.

### BACKGROUND ART

Liquid crystal display devices (display devices) incorporating a non-luminous liquid crystal display panel (display panel) generally also incorporate an illuminating device, such as a backlight unit, that supplies light to the liquid crystal display panel. There are many kinds of light sources for use in backlight units. For example, the backlight unit disclosed in Patent Document 1 listed below incorporates LEDs (light-emitting diodes) as a light source.

As shown in FIG. 17, such LEDs 122 are mounted on mounting boards 121, which are fitted to a backlight chassis 110 (the package including the backlight chassis 110 and the mounting boards 121 is referred to as the electronic package pg).

### LIST OF CITATIONS

### Patent Literature

Patent Document 1: JP-A-2009-158193

### SUMMARY OF INVENTION

### Technical Problem

The fitting of the mounting boards 121 to the backlight chassis 110 is achieved by use of screws 181 (see Patent Document 1, paragraph [0023]). Inconveniently, this increases the number of components, and accordingly the cost, of the backlight unit.

Moreover, the manufacturing process of the backlight unit inevitably involves operation for tightening many screws 181, complicating the manufacture of the backlight unit and resulting in a long manufacturing time.

Instead of screws 181, as shown in FIG. 18, double-sided adhesive tape 182 may be laid between the mounting boards 121 and the backlight chassis 110 for the fitting of the mounting boards 21 to the backlight chassis 110.

Inconveniently, however, using the double-sided adhesive tape 182 makes little difference than using screws 181 in increasing the number of components and complicating the manufacturing process (double-sided adhesive tape 182 may be used in combination with screws 181 to fit the mounting boards 121 to the backlight chassis 110, but doing so will naturally further increase the number of components and further complicates the manufacturing process).

The present invention has been made to overcome the inconveniences mentioned above, and aims to provide an electronic package, as a part of an electronic device (such as lighting devices), and the like that can be manufactured easily and at low cost.

### Solution to Problem

In an electronic package including a chassis and a mounting board fitted to the chassis, the chassis itself includes a fastening portion for fastening the mounting board.

With this design, there is no need for screws or double-sided adhesive tape for fastening the mounting board to the chassis. This helps reduce the number of components of, reduce the cost of, and simplify the manufacture of the electronic package.

It is preferable that the fastening portion be hook-shaped, rising from the bottom surface of the chassis and bent toward the bottom surface.

This fastening portion engages with the edge of the mounting board and in addition holds the mounting board between the tip portion of the hook and the bottom surface of the chassis, thus allowing the chassis to be stably fastened to the chassis.

It is preferable that, in a case where the hook-shaped fastening portion, at a rising segment which is the portion of the fastening portion rising from the bottom surface of the chassis, makes contact with the edge of the mounting board, a plurality of the fastening portion be arranged at opposite edges of the mounting board.

With this design, the fastening portions not only hold the mounting board between the tip portion of the hook and the bottom surface of the chassis but also hold the mounting board itself, thus allowing the chassis to be more stably fastened to the chassis.

It is preferable that the hook-shaped fastening portion include a rising segment which is the portion of the fastening portion rising from the bottom surface of the chassis and an overhanging segment which is the portion of the fastening portion crossing the rising segment and overhanging a mounting surface of the mounting board, and that a projection for increasing the pressing force against the mounting surface be formed on the overhanging segment.

With this design, in a case where the mounting board is held between the overhanging segment, which is the tip portion of the hook, and the mounting board, the projection formed on the overhanging segment, if any, makes the distance between the overhanging segment and the bottom surface of the chassis shorter by the height of the projection. This increases the pressing force of the overhanging segment against the mounting surface of the mounting board, thus allowing the fastening portion to more stably fasten the mounting board to the chassis.

It is preferable that the mounting board include a hole in which the projection on the overhanging segment fits. With this design, the projection on the fastening portion fits in the hole, and thereby prevents the mounting board from moving in any direction with respect to the fastening portion, hence the chassis. Thus, the fastening portion more stably fastens the mounting board to the chassis.

It is preferable that the hook-shaped fastening portion be formed by cutting and raising part of the bottom surface of the chassis. With this design, there is no need for an extra member for forming the fastening portion.

In addition, forming the fastening portion leaves an opening in the chassis. The opening makes it easier for outside air to enter from the outside, and thus, even when heat collects in the mounting board, the heat dissipates into outside air.

To allow more outside air to enter the electronic package, it is preferable that the bottom surface of the chassis have a window to be shaped like a skeleton.

In a case where heat collects in the mounting board, it is preferable that the chassis, which makes contact with the mounting board, be made of a high-heat-dissipation material such as aluminum alloy or carbon fiber-reinforced plastic. With this design, the heat collecting in the mounting board dissipates to the chassis.

Giving a coarse surface to at least part of the chassis increases the area of contact with outside air, and thus promotes the dissipation of the heat collecting in the mounting board to the chassis. In particular, locating the coarse-surfaced part of the chassis on a surface of the chassis facing outward permits it to make contact with outside air outside the electronic package, and this ensures the dissipation of the heat collecting in the mounting board.

Coarse-surfacing is not the only means of enhancing the dissipation of heat from the chassis. Instead, high-emissivity paint may be applied to at least part of the chassis. Particularly preferable is to locate the high-emissivity paint-applied part of the chassis on a surface of the chassis facing outward. Also with this design, the heat collecting in the mounting board dissipate via the high-emissivity paint to the chassis.

The present invention encompasses lighting devices that include an electronic package as described above in combination with a light source mounted on the mounting surface of the mounting board.

In such lighting devices, it is preferable that a reflective sheet covers the mounting surface, with the reflective surface of the reflective sheet facing outward and the reverse surface to the reflective surface facing the mounting surface, and that the reflective sheet have a perforation formed therein to expose only the light-exit region of the light source where the light source emits light.

With this design, only the light-exit region of the light source is exposed through the perforation, and this eliminates the part of the reflective surface that absorbs light (that is, its part between the rim of the perforation and the light-exit region). Thus, less of the light from the light source is lost before being output, permitting the illuminating device to produce high-quality light free from uneven light distribution.

The present invention encompasses display devices that include an illuminating device as described above in combination with a display panel which receives light from the illuminating device.

### Advantageous Effects of the Invention

With an electronic package according to the present invention, it is possible to fasten a mounting board to a chassis without using screws, double-sided adhesive tape, or the like. The electronic package thus contributes to reduced cost and a simplified manufacturing process.

### BRIEF DESCRIPTION OF DRAWINGS

FIG. 1 is an exploded perspective view of a liquid crystal display device.

FIG. 2 (A) is a plan view showing part of a backlight chassis etc. included in a liquid crystal display device; (B) is a sectional view of the backlight chassis etc. shown in (A) along line A1-A1′ as seen from the direction indicated by arrows; and (C) is a sectional view of the backlight chassis etc. shown in (A) along line B1-B1′ as seen from the direction indicated by arrows.

FIG. 3 is an exploded perspective view of LED modules and a backlight chassis to which the LED modules are fitted.

FIG. 4 is a perspective view showing LED modules in the process of being fitted to a backlight chassis.

FIG. 5 is a perspective view showing a backlight chassis having LED modules fitted to it.

FIG. 6 is a sectional view of a hook.

FIG. 7 is a plan view of a mounting board having a hole and an overhanging segment having a projection seen through the hole.

FIG. 8 is a plan view of a mounting board having holes.

FIG. 9 is a perspective view of a backlight chassis having rectangular windows formed in it to be shaped like a skeleton.

FIG. 10 is a plan view of a backlight chassis having rectangular windows formed in it to be shaped like a skeleton.

FIG. 11 is a plan view of a backlight chassis having rhombic windows formed in it to be shaped like a skeleton.

FIG. 12 is a plan view of a backlight chassis having circular windows formed in it to be shaped like a skeleton.

FIG. 13 is a plan view of a backlight chassis having triangular and trapezoid windows formed in a mixed fashion in it to be shaped like a skeleton.

FIG. 14 is a three-view diagram composed of a plan view of the rear side of the bottom surface of a backlight chassis and side views of the side surface of the backlight chassis as seen from two sides.

FIG. 15 (A) is a plan view showing part of a backlight chassis etc. included in a liquid crystal display device; (B) is a sectional view of the backlight chassis etc. shown in (A) along line A2-A2′ as seen from the direction indicated by arrows; and (C) is a sectional view of the backlight chassis etc. shown in (A) along line B2-B2′ as seen from the direction indicated by arrows.

FIG. 16 is graphs of front luminance plotted against position on a sectional view of a backlight unit.

FIG. 17 is an exploded perspective view of a conventional backlight unit.

FIG. 18 is an exploded perspective view of a conventional backlight unit.

### DESCRIPTION OF EMBODIMENTS

### Embodiment 1

An embodiment of the present invention will be described below with reference to the accompanying drawings. For convenience' sake, hatching and reference signs are occasionally omitted, in which case any other relevant drawings are to be referred to. Conversely, also for convenience' sake, hatching is occasionally used other than in sectional views. A solid black dot appearing on arrows indicates the direction perpendicular to the plane of paper.

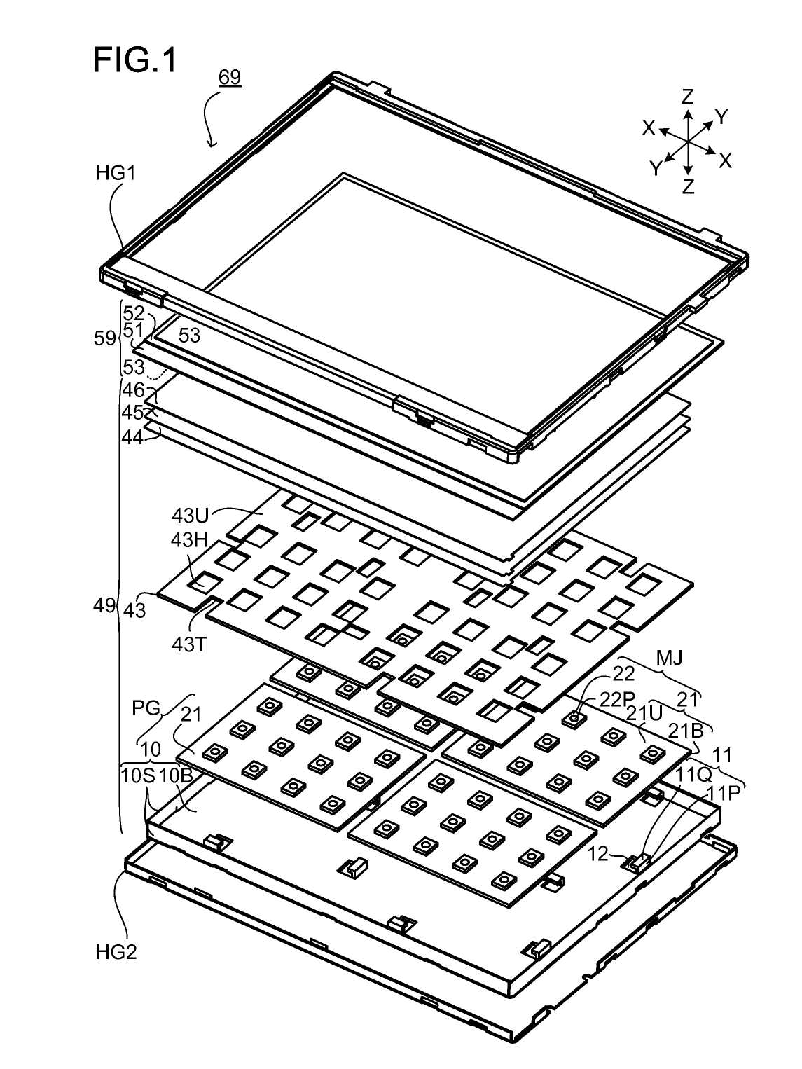

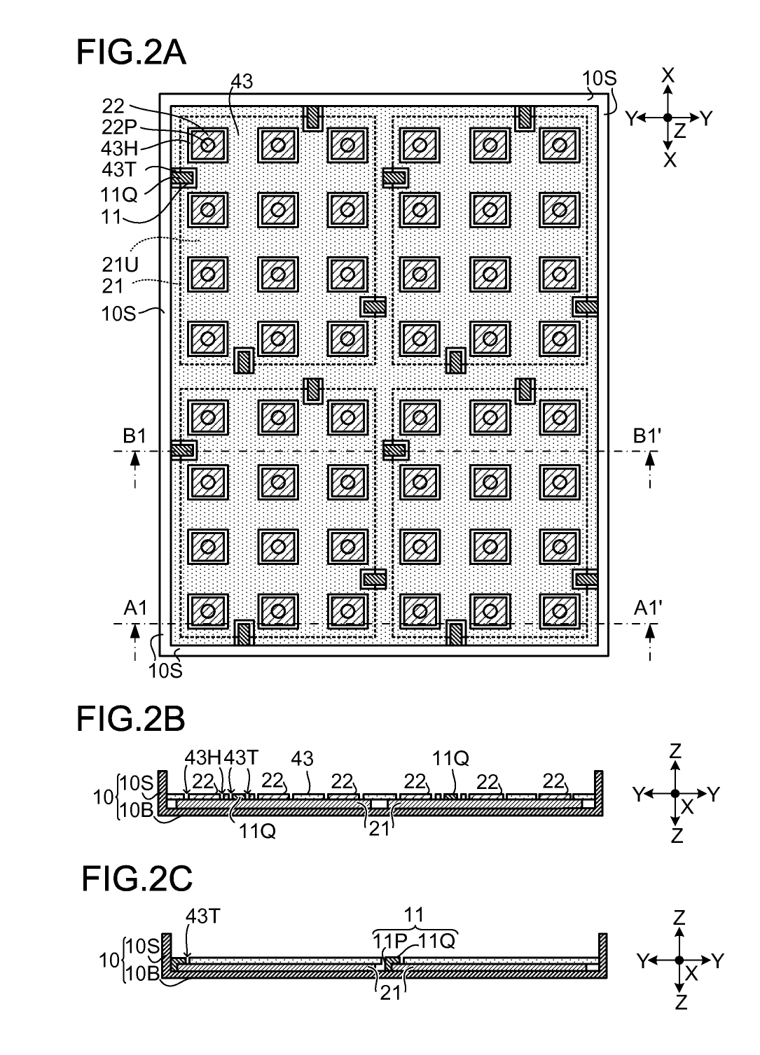

FIG. 1 is an exploded perspective view of a liquid crystal display device. FIG. 2A is a plan view showing part of a backlight chassis 10 etc. included in the liquid crystal display device 69 (more specifically, a plan view of the backlight chassis 10 having, stacked on its bottom surface 10B, LED modules MJ and a reflective sheet 43). FIG. 2B is a sectional view of the backlight chassis 10 etc. shown in FIG. 2A along line A1-A1′ as seen from the direction of arrows, and FIG. 2C is a sectional view of the backlight chassis 10 etc. shown in FIG. 2A along line B1-B1′ as seen from the direction of arrows.

As shown in FIG. 1, the liquid crystal display device 69 includes a liquid crystal display panel 59, a backlight unit (illuminating device) 49 which supplies light to the liquid crystal display panel 59, and a housing HG (a front housing HG1 and a rear housing GH2) which holds those from opposite sides.

The liquid crystal display panel 59 includes an active matrix substrate 51 and a counter substrate 52 between which liquid crystal (not shown) is filled. Although not shown, gate signal lines and source signal lines are arranged so as to cross each other, and at their intersections, switching devices (for example, thin-film transistors) are arranged which are needed to adjust the voltage applied to the liquid crystal.

A polarizing film 53 is fitted on the light-entrance side of the active matrix substrate 51, and another polarizing film 53 is fitted on the light-exit side of the counter substrate 52. Structured as described above, the liquid crystal display panel 59 displays an image by exploiting variation of transmittance resulting from inclination of liquid crystal molecules.

Next, a description will be given of the backlight unit 49, which is located immediately under the liquid crystal display panel 59 and which supplies light (backlight) to the liquid crystal display panel 59. The backlight unit 49 includes LED modules (light-emitting modules) MJ, a backlight chassis 10, a reflective sheet 43, a diffusive member 44, a prism sheet 45, and a prism sheet 46.

The LED modules MJ include mounting boards 21 and LEDs (light-emitting diodes) 22.

The mounting boards 21 are, for example, rectangular boards, and have a plurality of electrodes (not shown) arranged on their mounting surface 21U. On top of these electrodes, LEDs 22 as light-emitting elements are fitted. The electrodes are arranged, on the mounting surface 21U of each mounting board 21, along two mutually crossing (for example, mutually perpendicular) directions (that is, the electrodes are in a lattice arrangement).

In FIG. 1, four mounting boards 21 (hence LED modules MJ) are in a 2×2 lattice arrangement. This, however, is not meant as a limitation to that specific arrangement and that specific number of mounting boards 21. On each mounting board 21, LEDs 22 are mounted in a 4×4 lattice arrangement. This, however, is not meant as a limitation to that specific arrangement and that specific number of LEDs 22.

So long as the LEDs 22 are arranged close together so that the light from them mixes to produce planar light, there is no particular restriction on the number and arrangement of LEDs 22 and the number and arrangement of LED modules MJ. The mounting boards 21 may be hard boards made of a glass epoxy material or a paper phenolic material; or boards made of a composite epoxy material (CEN) composed of nonwoven glass fabric, glass cloth, and epoxy resin; or metal boards made of aluminum or iron.

For convenience' sake, in the group of LEDs 22 in a lattice arrangement, the direction of rows with a larger number of LEDs 22 is referred to as the X direction, and the direction of rows with a smaller number of LEDs 22 is referred to as the Y direction; the direction crossing (for example, perpendicular to) both the X and Y directions is referred to as the Z direction (the X direction corresponds to the longer sides of the screen of the liquid crystal display panel 59, and the Y direction corresponds to the shorter sides of the screen of the liquid crystal display panel 59).

The LEDs 22 are light sources (light-emitting devices, point light sources), and emit light by receiving electric current via the electrodes on the mounting boards 21. Among the LEDs 22 in a lattice arrangement, the directions in which they emit light are aligned in one direction (the Z direction) so that the light from them mixes to produce planar light. Accordingly, the light-exit apertures 22P of the LEDs 22 point in the Z direction (a light-exit aperture 22P is the region of an LED 22 in which it emits light).

As shown in FIG. 1, the backlight chassis (chassis) 10 is a box-shaped member, and accommodates, on its bottom surface 10B, the LED modules MJ. The backlight chassis 10 will be described in detail later.

The reflective sheet 43 is an optical sheet having a reflective surface 43U, and covers the LED modules MJ in a lattice arrangement with the reverse surface to the reflective surface 43U facing the LED modules MJ. The reflective sheet 43 has perforations 43H at positions corresponding to the LEDs 22 on the LED modules MJ so that the LEDs 22 are exposed through the reflective surface 43U.

Such being the structure, even when part of the light emanating from the LEDs 22 travels toward the bottom surface 10B of the backlight chassis 10, it is reflected on the reflective surface 43U of the reflective sheet 43, and thus it then travels away from the bottom surface 10B. The presence of the reflective sheet 43, therefore, permits the light from the LEDs 24 to travel toward the diffusive member 44 opposite the reflective surface 43U without loss.

The diffusive member 44 is a plate-shaped optical member which is stacked on the reflective sheet 43 over the mounting surface 21U on which the LEDs 22 are mounted. The diffusive member 44 receives and diffuses the light emanating from the LED modules MJ. That is, the diffusive member 44 diffuses the planar light formed by the LED modules MJ so that it illuminates the entire area of the liquid crystal display panel 59.

The prism sheets 45 and 46 are, for example, optical members that have prism shapes on their sheet plane to deflect light, and are located so as to cover the diffusive member 44. The prism sheets 45 and 46 condense, and thereby increase the luminance of, the light emerging from the diffusive member 44. The directions in which the light condensed by the prism sheets 45 and 46, respectively, is made to diverge are in a mutually crossing relationship.

In the backlight unit 49 (a direct backlight unit) structured as described above, the planar light formed by the LED modules MJ is passed through a plurality of optical members 44 to 46, and is supplied to the liquid crystal display panel 59. Receiving backlight BL from the backlight unit 49, the non-luminous liquid crystal display panel 59 provides enhanced display performance.

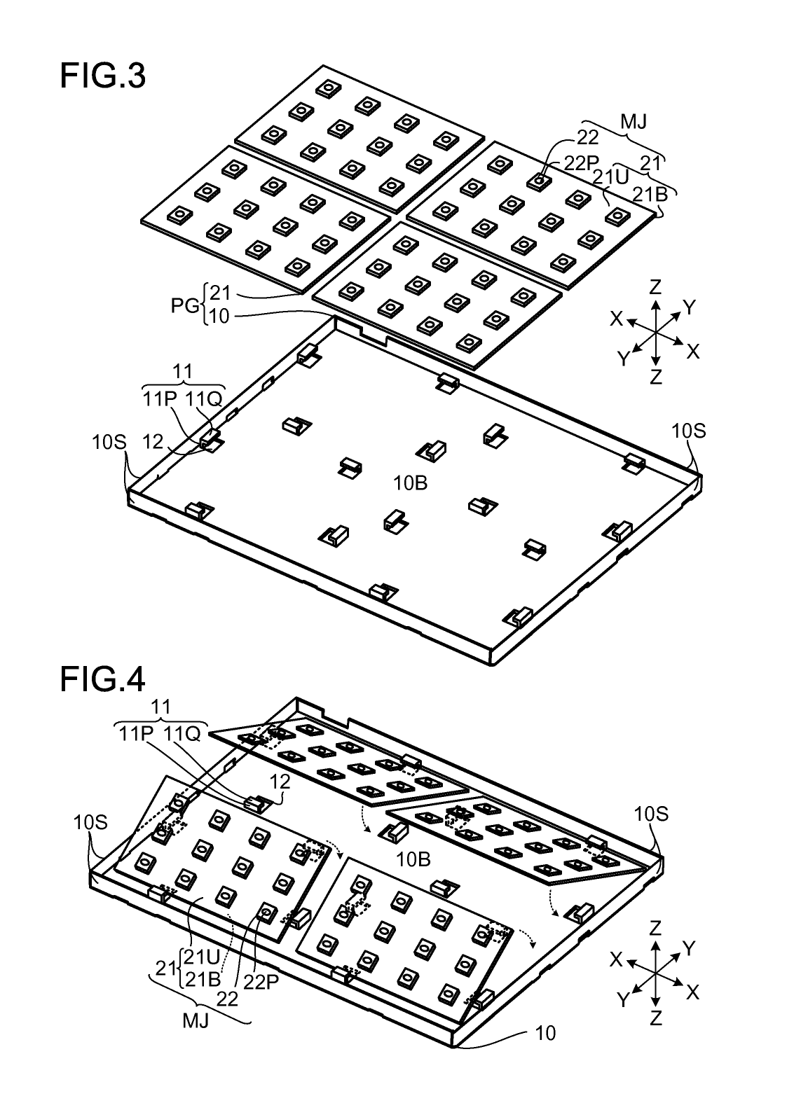

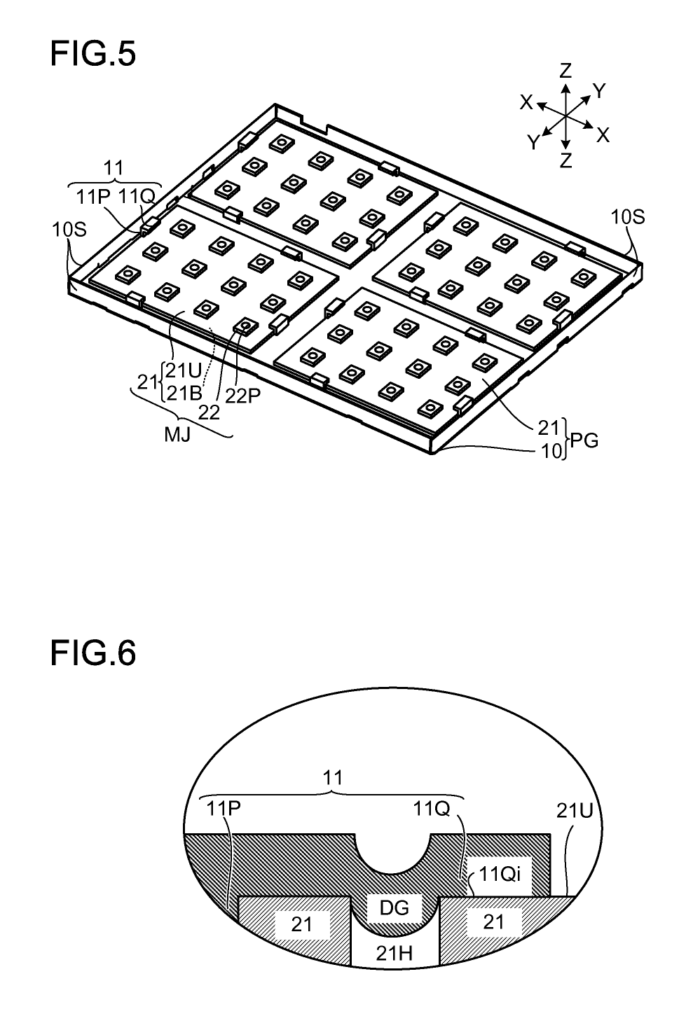

Now, the backlight chassis 10 will be described in detail with reference to, in addition to FIGS. 1 and 2A to 2C, also FIGS. 3 to 5. FIG. 3 is an exploded perspective view of four LED modules MJ and a backlight chassis 10 to which they are fitted. FIG. 4 is a perspective view showing the LED modules MJ in the process of being fitted to the backlight chassis 10. FIG. 5 is a perspective view of the backlight chassis 10 having the LED modules MJ fitted to it (the package including the backlight chassis 10 and the mounting boards 21 is referred to as the electronic package PG).

As shown in FIG. 1, forming an unclosed-loop-shaped cut in the bottom surface 10B of the backlight chassis 10 produces a segment that can be raised from the bottom surface 10B. The segment rises from the bottom surface 10B of the backlight chassis 10 and then bends toward the bottom surface 10B. Thus, the segment has the shape of a bent hook. Such a segment will be referred to as a hook 11. The hook 11 is formed of the same material as the backlight chassis 10 (for example, flexible metal or resin).

The hook (fastening portion) 11 thus includes a rising segment 11P, which is the portion of the hook 11 that rises from the bottom surface 10B of the backlight chassis 10, and an overhanging segment 11Q, which is the portion of the hook 11 that crosses the rising segment 11P and that overhangs the mounting surface 21U of a mounting board 21. That is, as a whole, the hook 11 has a bent form like the letter L.

The rising segment 11P is the portion of the hook 11 between where it connects to the bottom surface 10B of the backlight chassis 10 and where it bends midway (not necessarily precisely in the middle), and rises from the bottom surface 10B in a direction approximately perpendicular to it. The length of the rising segment 11P is about the same as the thickness of the mounting board 21.

The overhanging segment 11Q is the portion of the hook 11 between where it bends midway and its tip, and overhangs the bottom surface 10B of the backlight chassis 10. Thus, between the overhanging segment 11Q and the bottom surface 10B of the backlight chassis 10, there is a space in which a member can be held. In particular, when the length of the hook 11p supporting the overhanging segment 11Q is about the same as the thickness of a mounting board 21, between the overhanging segment 11Q and the bottom surface 10B of the backlight chassis 10, there is a space in which the mounting board 21 can be fit.

For example as shown in FIG. 3, four hooks 11 are arranged in a loop, one at each of the four sides of a mounting board 21, which is rectangular. More specifically, each hook 11 is arranged to face a side of the mounting board 21, with the tip of the overhanging segment 11Q pointing to that side of the mounting board 21, so that the side (edge) is held between the overhanging segment 11Q and the bottom surface 10B of the backlight chassis 10.

As shown in FIG. 4, a mounting board 21 is first held inclined relative to the bottom surface 10B of the backlight chassis 10, and one side of the mounting board 21 nearest to the bottom surface 10B is put against a hook 11. As the mounting board 21 is then inclined toward the bottom surface 10B (as indicated by dotted-line arrows), the other sides of the mounting board 21 approach other hooks 11. These hooks 11 warp against the approaching mounting board 21 and then straighten back, so that eventually, as shown in FIG. 5, all the sides of the mounting board 21 is held between the overhanging segments 11Q of the hooks 11 and the bottom surface 10B of the backlight chassis 10.

Thus, the mounting board 21 is held between the overhanging segments 11Q of four hooks 11 and the bottom surface 10B of the backlight chassis 10, and is thereby prevented from moving upward (in the Z direction) off the bottom surface 10B. In addition, the mounting board 21 is also held between the rising segments 11P of opposite hooks 11, and is thereby prevented from moving across the plane of the bottom surface 10B of the backlight chassis 10 (i.e., across the XY plane defined by the X and Y directions).

Providing, in this way, the backlight chassis 10 itself with a hook 11 for fastening a mounting board 21 eliminates the need for an extra holding member (such as screws and double-sided adhesive tape) for fastening the mounting board 21 to the backlight chassis 10. This helps reduce the cost of the backlight unit 49, hence the liquid crystal display device 69.

Moreover, the hook 11 is continuous with the backlight chassis 10. Thus, even when the backlight unit 49 is subjected to impact or vibration, the hook 11 will not come off the backlight chassis 10 (the hook 11 is highly resistant to impact).

In a case where the mounting board 21 is fastened to the backlight chassis 10 by use of a fastening member such as screws, the great trouble of turning the screws and the like is unavoidable. With hooks 11, in contrast, simple fitting makes the trouble of fastening the mounting board 21 to the backlight chassis 10 comparatively small. This alleviates the trouble involved in the manufacture of the backlight unit 49, hence the liquid crystal display device 69.

On the other hand, in a case where the mounting board 21 is fastened to the backlight chassis 10 by use of a fastening member such as double-sided adhesive tape, not only is the trouble of applying the double-sided adhesive tape unavoidable, but also the backlight unit 49 may become thicker by the thickness of the double-sided adhesive tape. With hooks 11, in contrast, not only is the trouble of fastening the mounting board 21 to the backlight chassis 10 comparatively small, but also the backlight unit 49, hence the liquid crystal display device 69, does not become thicker.

Moreover, on the occasion of repair and the like, a mounting board 21 that is fitted to the backlight chassis 10 with screws or double-sided adhesive tape is difficult to remove. With hooks 11, in contrast, the mounting board 21 is easy not only to fit to but also to remove from the backlight chassis 10. It is thus possible to realize a backlight unit 49 that is easy to rework.

Although the above description deals with a case where one mounting board 21 is fastened to the bottom surface 10B of the backlight chassis 10 by use of four hooks 11, there is no particular restriction on the number of hooks 11. Specifically, the number of hooks 11 may be three or less, or five or more.

In a case where a hook 11, at its rising segment 11P, makes contact with the edge of a mounting board 21, however, it is preferable that hooks 11 be arranged one at each of opposite sides of the mounting board 21 (that is, it is preferable that one hook 11 is provided at one side of the mounting board 21 and another hook 11 is provided at another side of the mounting board 21 opposite to the first-mentioned side).

With this design, the mounting board 21 is prevented from moving across the plane of the bottom surface 10B in the direction crossing the sides of the mounting board 21 at which it is held by the hooks 11 (that is, in the direction in which the hooks 11 are arranged) (that is, not only does each hook 11 hold the edge of the mounting board 21, but a plurality of hooks 11 also holds the mounting board 11 itself, so that the mounting board 21 is more stably fastened to the backlight chassis 10). To prevent the mounting board 21 from moving in any direction across the plane, it is necessary that, for example as described above, all sides of the mounting board 21 be held by hooks 11).

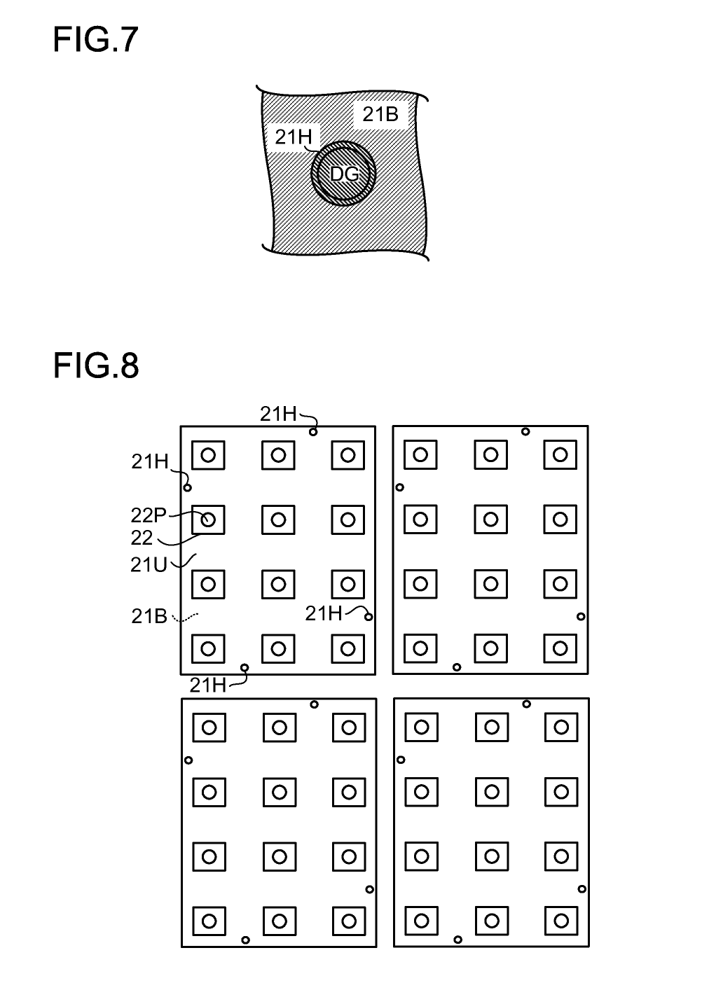

Instead, as shown in a sectional view in FIG. 6 and a partial plan view in FIG. 7, a projection DG may be formed on the surface (inner surface 11Qi), facing the mounting board 21, of the overhanging segment 11Q of the hook 11, and a hole (or hollow) 21H in which the projection DG fits may be formed on the mounting board 21. With a single hook 11, then, the mounting board 21 can be prevented from moving in any direction across the plane of the backlight chassis 10 (the mounting board 21 is prevented from rattling and shifting).

In particular in a case where one mounting board 21 is fastened with one hook 11, it is preferable that the hole 21H be formed not circular but polygonal with three (triangular) or more vertices, and that the projection DG that fits in the hole 21H be formed not hemispherical but in the shape of a block that fits the hole 21H. With this design, the mounting board 21 is prevented from rotating about the projection DG.

The number of hooks 11 including a DG is not limited to one for one mounting board 21; as shown in a plan view in FIG. 8, holes 21H may be formed one for each side of the mounting board 21, with hooks 11 arranged in correspondence to those holes 21H. With this design, the mounting board 21 is more reliably prevented from moving with respect to the backlight chassis 10 (that is, the mounting board 21 is prevented from rattling and shifting, and the mounting board 21 is fastened to the backlight chassis 10 with increased strength).

Instead, whereas a projection DG is formed on the hook 11, no hole 21H for the projection DG to fit in may be formed. Usually, forming the projection DG on the inner surface 11Qi of the overhanging segment 11Q facing the mounting surface 21U of the mounting board 21 makes the distance between the tip of the projection DG and the bottom surface 10B of the backlight chassis 10 shorter than the distance between the inner surface 11Qi of the overhanging segment 11Q and the bottom surface 10B (that is, the distance between the overhanging segment 11Q and the bottom surface 10B of the backlight chassis 10 is made shorter by the height of the projection DG).

Then, when the hook 11, between it and the bottom surface 10B of the backlight chassis 10, holds the mounting board 21, the projection DG increases the pressing force against the mounting surface 21U. Thus, even with no hole 21H in the mounting board 21, the hook 11 can satisfactorily prevent the mounting board 21 from moving. The cost of forming the hole 21H in the mounting board 21 is also cut.

As the LEDs 22 emit light, they generate heat, and the heat collects in the LEDs 22 and also in the mounting board 21 on which the LEDs 22 are mounted. The heat causes not only lowering of the light emission efficiency of the LEDs 22 but also deterioration (secular deterioration) of the mounting board 21.

In a case where the backlight chassis 10 is made of, for example, metal, it is preferable that the hook 11 shown in FIG. 3 be formed by cutting and raising part of the bottom surface 10B of the backlight chassis 10. With this design, forming the hook 11 in the backlight chassis 10 leaves there an opening (ventilation opening) 12 that leads to the outside.

Thus, when the LED modules MJ are placed over the bottom surface 10B of the backlight chassis 10 and are fastened to backlight chassis 10 with hooks 11, the inside of the backlight unit 49 is not hermetically closed, and thus outside air enters through ventilation openings 12. Thus, even when the LEDs 22 generate heat, the heat not only dissipates by conducting to the backlight chassis 10 with which the mounting board 21 makes contact, but is also lowered by outside air entering through the ventilation openings 12. The heated air is then discharged outside (the heat is rejected).

That is, the heat collecting in the LEDs 22 and in the mounting boards 21 dissipate by conducting not only to the backlight chassis 10 but also to outside air (that is, heat dissipates also by convection). This prevents deterioration of the LEDs 22 and the mounting boards 21, and prevents lowering of the light emission efficiency of the LEDs 22 (that is, it prevents lowering of the luminance of the planar light from the backlight unit 49, and thereby permits light with desired luminance to be produced with comparatively low power consumption). In addition, since the hooks 11 are formed by cutting and raising part of the bottom surface 10B of the backlight chassis 10, there is no need for an extra member for forming the hooks 11.

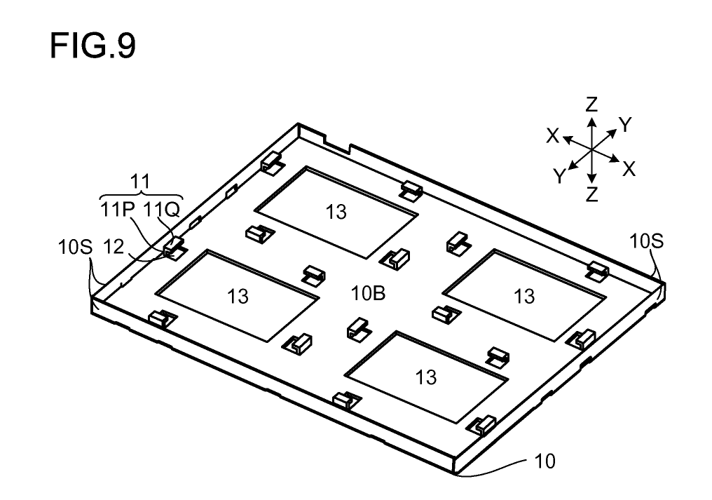

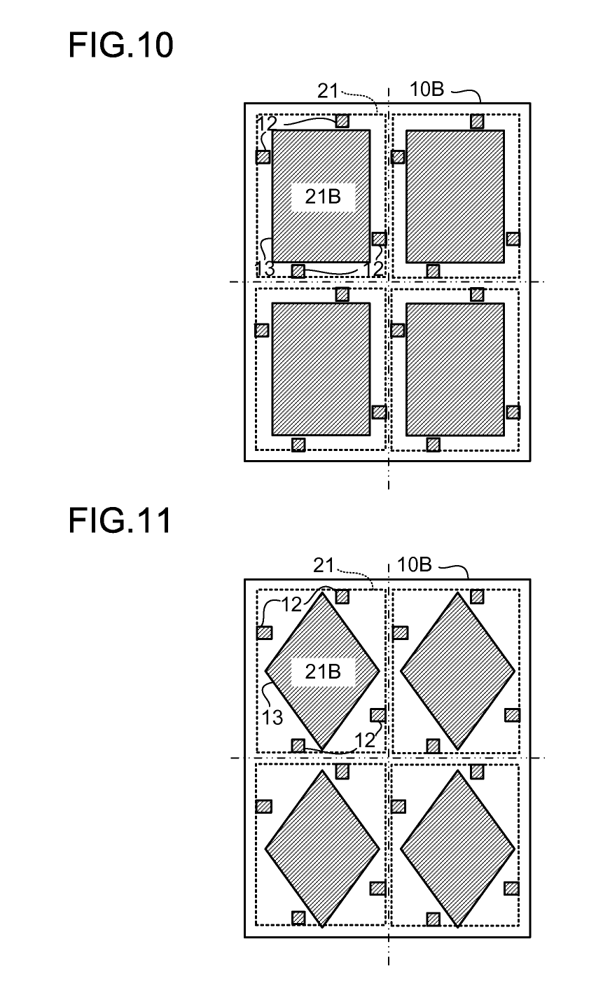

For further dissipation of the heat collecting in the LED modules MJ, a window 13 may be formed in the bottom surface 10B of the backlight chassis 10 to make it shaped like a skeleton. For example, as shown in a perspective view in FIG. 9 and a plan view in FIG. 10, it is preferable that, on the rear side of a mounting board 21 fastened to the bottom surface 10B of the backlight chassis 10 (on the side of the reverse surface 21B to the mounting surface 21U on which LEDs 22 are mounted), a window 13 be formed which is geometrically similar to the contour of the mounting board 21.

With this design, owing to the window 13 which has a similar function to and larger than the ventilation opening 12, the heat collecting in the LED modules MJ dissipates to outside air more efficiently.

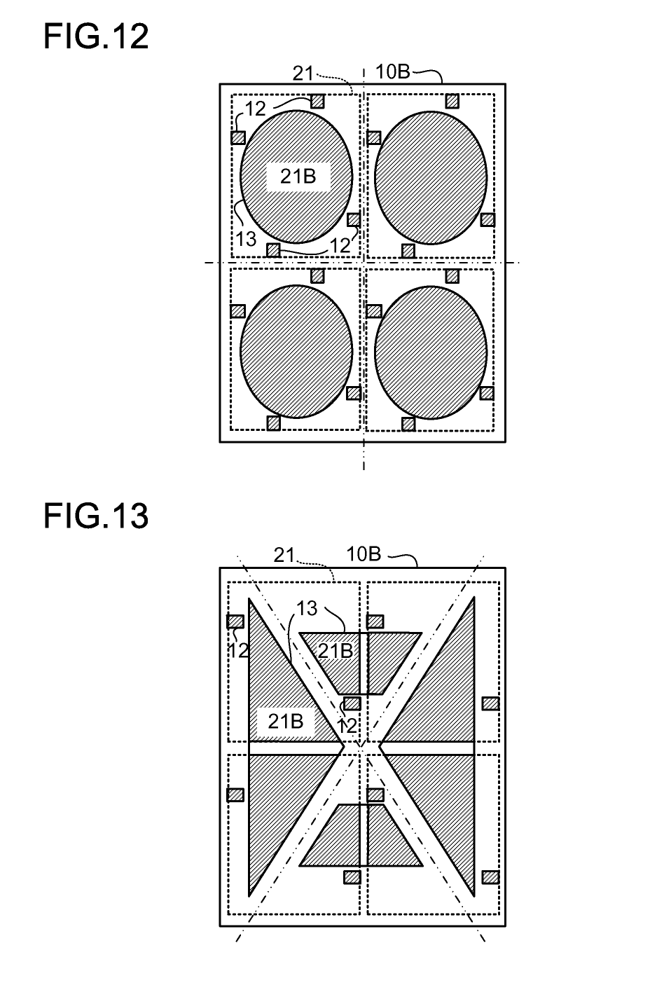

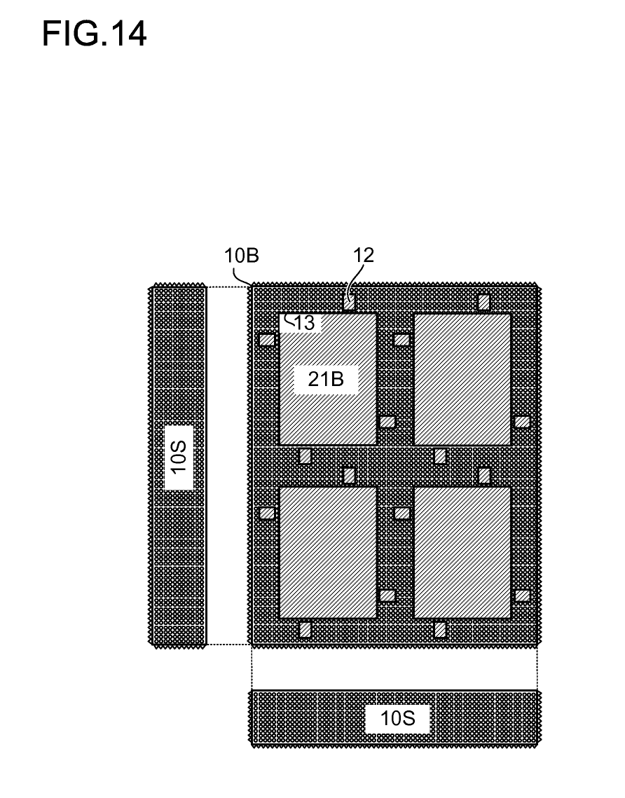

The shape of the window 13 is not limited to one geometrically similar (for example, rectangular) to that of the mounting board 21. For example, the window 13 may be rhombic as shown in FIG. 11, or circular as shown in FIG. 12. Although in FIGS. 10 to 12, windows 13 of the same type are formed in the bottom surface 10B of one backlight chassis 10, this is not meant as a limitation; as shown in FIG. 13, triangular windows 13 and trapezoid windows 13 may be formed in a mixed fashion in the bottom surface 10B.

As shown in FIGS. 10 to 13, it is preferable that, of the bottom surface 10B of the backlight chassis 10 shaped like a skeleton, the frame-like portion (indicated by dash-dot-dot lines) other than the windows 13 be left so as to have a crossing shape. With the frame-like portion of the bottom surface 10B left to have a crossing shape, even through the backlight chassis 10 is lighter by the weight removed for the windows 13, the backlight chassis 10 remains satisfactorily strong.

An example of the material of the backlight chassis 10 described above is metal, and there is no particular restriction on the kind of metal. For example, when the material of the backlight chassis 10 is metal, iron may be used as one example; instead, as a metal lighter and having higher heat dissipation than iron, aluminum or an aluminum alloy (for example, any of Al—C, Al—Mn, Al—Si, Al—Mg, Al—Mg—Si, and Al—Mg—Zn alloys) may be used.

Forming the backlight chassis 10 out of a material with comparatively high thermal conductivity as mentioned above permits the heat collecting in the LEDs 22 and the mounting boards 21 to dissipate by conducting to the backlight chassis 10 efficiently. This prevents deterioration of the LEDs 22 and the mounting board 21, and hence prevents lowering of the light emission efficiency of the LEDs 22. Moreover, using an aluminum alloy, which has a specific gravity about one-third of that of iron, makes the backlight unit 49, hence the liquid crystal display device 69, lighter.

The material of the backlight chassis 10 may be resin. For example, the backlight chassis 10 may be formed of resin integrally with hooks 11. One example of such resin is carbon fiber-reinforced plastic (CFRP). CFRP has a specific gravity of about 1.4 g/cm³, which is about half that of an aluminum alloy, namely about 2.7 g/cm³, and in addition has higher thermal conductivity than an aluminum alloy.

Thus, a backlight chassis 10 made of CFRP, compared with one made of aluminum alloy, prevents lowering of the light emission efficiency of the LEDs 2 more effectively and is lighter.

Other means, than proper selection of the material of the backlight chassis 10, of efficiently dissipating the heat collecting in the LED modules MJ include the following.

One means is to form a coarse surface on at least part of the backlight chassis 10 as shown in a three-view diagram in FIG. 14 (composed of a plan view of the rear side of the bottom surface 10B of the backlight chassis 10 and two side views of the side surface of the backlight chassis 10 as seen from two directions).

Forming a coarse surface on the side surface 10S and bottom surface 10B of the backlight chassis 10 in this way increases the surface area over which it makes contact with outside air, and thus the heat of the LED modules MJ that has conducted to the backlight chassis 10 dissipates efficiently.

In particular, forming a coarse surface on an outer surface of the backlight chassis 10, that is, on the outer (outward facing) side of the side surface 10S and on the outer (outward facing) side of the bottom surface 10B, permits the backlight chassis 10 with that coarse surface to make contact with outside air (that is, fresh outside air) outside the backlight unit 49, and this ensures dissipation of heat.

The surface coarsing is not restricted by the material of the backlight chassis 10. That is, surface coarsing may be applied irrespective of whether the backlight chassis 10 is made of metal, such as iron, aluminum, or aluminum alloy, or resin, such as CFRP.

Another means of efficiently dissipating the heat collecting in the LED modules MJ is to apply high-emissivity paint to the backlight chassis 10. High-emissivity paint is paint that exhibits increased heat emission by its containing a non-metal substance, such as carbon (with an emissivity of about 0.8), graphite (with an emissivity of about 0.93), or the like, or a metal compound, such as nickel oxide (NiO, with an emissivity of about 0.9), silicon dioxide (SiO₂, with an emissivity of bout 0.83), tantalum carbide (TaC, with an emissivity of about 0.81), or the like.

Applying such high-emissivity paint to, for example, the side surface 10S and bottom surface 10B of the backlight chassis 10 increases the emission (radiation) of far-infrared rays from those surfaces. Thus, a backlight chassis 10 having high-emission paint applied to at least part of it ensures dissipation of heat.

In particular, applying high-emission paint to the backlight chassis 10 on the outer (outward facing) side of the side surface 10S, around four sides, and on the outside side (rear side) of the bottom surface 10B permits the backlight chassis 10 with that painted part to emit heat into outside air outside the backlight unit 49, and this ensures dissipation of heat.

The high-emissivity paint is not restricted by the material of the backlight chassis 10 to which it is applied. That is, high-emissivity paint may be applied irrespective of whether the backlight chassis 10 is made of metal, such as iron, aluminum, or aluminum alloy, or resin, such as CFRP. High-emissivity paint may be applied to a coarse surface provided on, for example, the outer surface of the backlight chassis 10.

High-emissivity paint may be applied to the reverse surface 21B of the mounting board 21 of the LED modules MJ. Also with this design, the heat collecting in the LED modules MJ dissipates efficiently. There is no particular restriction on how the high-emission paint is applied; it may be applied, for example, by spraying or with a brush.

### Other Embodiments

The present invention may be carried out in any manners other than specifically described by way of embodiments above, and allows many modifications and variations.

For example, there is no particular restriction on how the backlight chassis 10, including hooks 11 and windows 13, is formed, For example, in a case where the backlight chassis 10 is made of metal, it may be formed by subjecting flat sheet metal with a thickness of about 0.5 to about 2 mm to pressing, punching, bending, or other processing. In a case where the backlight chassis 10 is made of resin, it may be formed by molding.

There is no particular restriction on how a coarse surface is formed on the backlight chassis 10. For example, to form a coarse surface with fine irregularities on different surfaces of the backlight chassis 10, etching is performed by use of a mask pattern film having a coarse surface pattern with fine irregularities. To form a coarse surface with fine irregularities on different surfaces of the backlight chassis 10 at low cost, embossing is performed which involves swage-shaping using a die having a coarse surface pattern.

In the backlight unit 49 which outputs the light from the LEDs 22 mounted on the mounting surface 21U of the mounting boards 21, as shown in FIG. 1, the reflective sheet 43 covers the mounting surface 21U with the reflective surface 43U facing the outside and the reverse surface to the reflective surface 43U facing the mounting surface 21U.

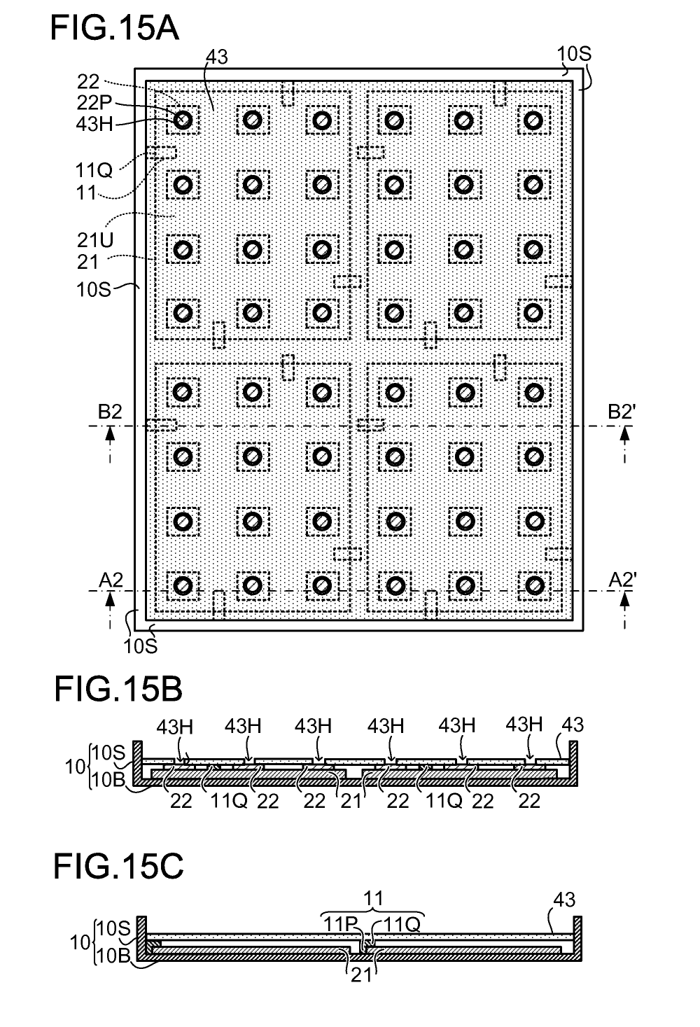

As shown in FIG. 15A to 15C, in the reflective sheet 43, there may be formed perforations 43H through which only the light exit apertures 22P (light-exit region) of the LEDs 22 are exposed to the outside. FIG. 15A is a plan view of the backlight chassis 10 having, stacked on its bottom surface 10B, the LED modules MJ and the reflective sheet 43; FIG. 15B is a sectional view of the backlight chassis 10 etc. shown in FIG. 15A along line A2-A2′ as seen from the direction of arrows; and FIG. 15C is a sectional view of the backlight chassis 10 etc. shown in FIG. 15A along line B2-B2′ as seen from the direction of arrows.

When a comparison is made between the area of a reflective sheet 43 that exposes only the light-exit apertures 22P of the LEDs 22 through the perforations 43H and the area of a reflective sheet 43 that exposes the entire LEDs 22 through the perforations 43H, the reflective sheet 43 that exposes only the light-exit apertures 22P of the LEDs 22 has a larger reflective surface 43U.

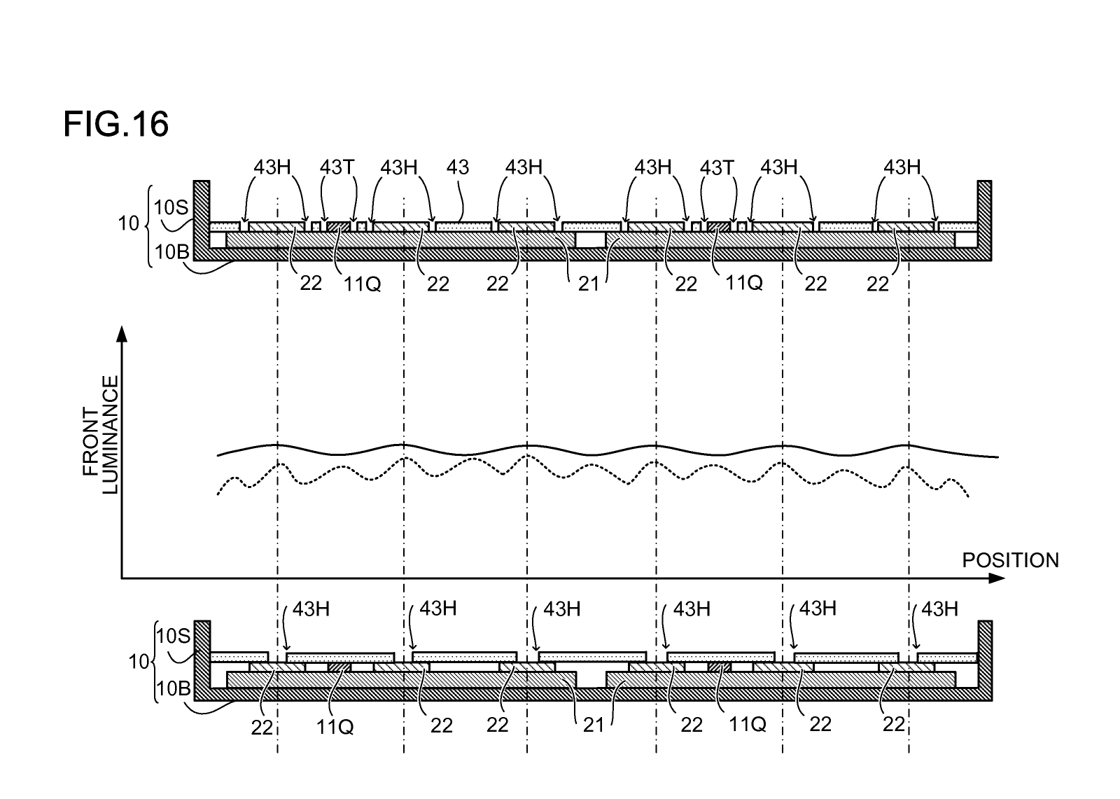

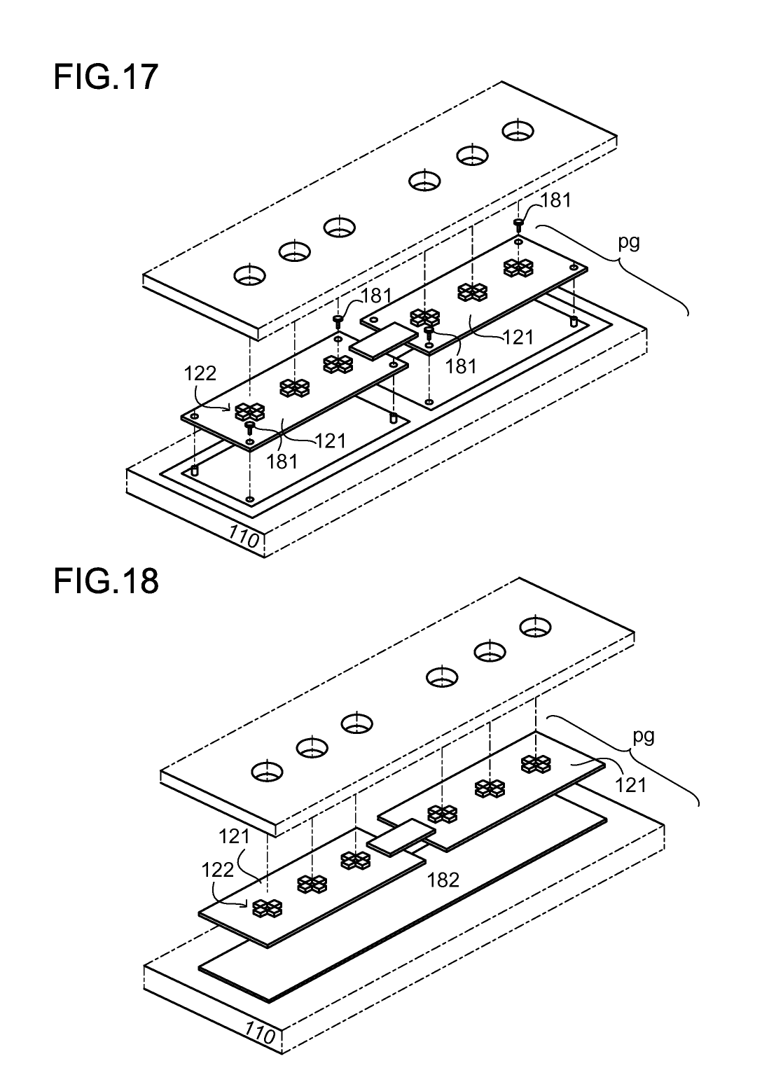

Accordingly, the front luminance plotted against the position on a sectional view of the backlight unit 49 describes curves as shown in FIG. 16. Specifically, the solid-line curve represents the front luminance attributable to the light emitted from the LEDs 22 and the light reflected from a reflective sheet 43 that exposes only the light-exit apertures 22P of the LEDs 22 through the perforations 43H, and the dotted-line curve represents the front luminance attributable to the light emitted from the LEDs 22 and the light reflected from a reflective sheet 43 that exposes the entire LEDs 22 through the perforations 43H (a sectional view of the backlight unit 49 corresponding to the solid-line curve is shown under the graphs, and a sectional view of the backlight unit 49 corresponding to the dotted-line curve is shown over the graphs).

The two graphs reveal that the solid-line curve indicates less difference than the dotted-line curve. That is, the planar light formed by the light emitted from the LEDs 22 and the light reflected from a reflective sheet 43 that exposes only the light-exit apertures 22P of the LEDs 22 through the perforations 43H is less likely to have uneven light distribution. This results from the portions of the LEDs 22 around the light-exit apertures 22P, which do not reflect light, being covered by the reflective sheet 43, leading to increased reflectance.

That is, the part of the reflective surface 43U of the reflective sheet 43 where it does not reflect light (absorbing portion, the portion between the rim of the perforations 43H and the light-exit apertures 22P) is eliminated, with a result that, whereas a reflective sheet 43 with an absorbing portion has a reflectance of about 50% to 80%, a reflective sheet 43 with narrowed perforations 43H and hence a smaller absorbing portion has a reflectance of 95% or more.

With this design, it is possible to increase the luminance of the planar light without increasing the electric current supplied to the LEDs 22. As a result, the backlight unit 49 can provide high-quality planar light with less uneven light distribution with comparatively low power consumption (that is, light with desired luminance can be produced with comparatively low power consumption).

Making the height of the LEDs 22 (that is, the height from the mounting surface 21U to the light-exit apertures 22P) and the thickness of the overhanging segments 11Q of the hooks 11 approximately equal as shown in FIG. 15B makes it more likely that the reflective sheet 43, when laid over the mounting surface 21U having the LEDs 22 mounted on it, lies flat without wrinkles.

Laying the reflective sheet 43 flat in that way makes it easier for the light reflected from it to travel toward the diffusive member 43, and makes loss of light less likely. Thus, the light output from the backlight unit 49 has still less uneven light distribution.

### LIST OF REFERENCE SIGNS

10 backlight chassis (chassis)
11 hook (fastening portion)
11P rising segment
11Q overhanging segment
DG projection
11B bottom surface of backlight chassis
11S side surface of backlight chassis
12 ventilation opening
13 opening
21 mounting board
21U mounting surface
21b reverse surface to mounting surface
21H hole
22 LED
22P light-exit aperture (light-exit region)
MJ LED module
43 reflective sheet
43H perforation
44 diffusive member
45 prism sheet
46 prism sheet
49 backlight unit (lighting device)
59 liquid crystal display panel (display panel)
69 liquid crystal display device (display device)

1. An electronic package comprising:
a chassis; and
a mounting board which is fitted to the chassis,
wherein the chassis itself includes a fastening portion for fastening the mounting board.

2. The electronic package according to claim 1,
wherein the fastening portion is hook-shaped, rising from a bottom surface of the chassis and bent toward the bottom surface.

3. The electronic package according to claim 2,
wherein, in a case where the hook-shaped fastening portion, at a rising segment which is a portion of the fastening portion rising from the bottom surface of the chassis, makes contact with an edge of the mounting board,
a plurality of the fastening portion are arranged at opposite edges of the mounting board.

4. The electronic package according to claim 2,
wherein the hook-shaped fastening portion includes a rising segment which is a portion of the fastening portion rising from the bottom surface of the chassis and an overhanging segment which is a portion of the fastening portion crossing the rising segment and overhanging a mounting surface of the mounting board, and
a projection for increasing a pressing force against the mounting surface is formed on the overhanging segment.

5. The electronic package according to claim 4,
wherein the mounting board includes a hole in which the projection on the overhanging segment fits.

6. The electronic package according to claim 2,
wherein the hook-shaped fastening portion is formed by cutting and raising part of the bottom surface of the chassis.

7. The electronic package according to claim 1,
wherein the bottom surface of the chassis has a window to be shaped like a skeleton.

8. The electronic package according to claim 1,
wherein the chassis is made of aluminum alloy or carbon fiber-reinforced plastic.

9. The electronic package according to claim 1,
wherein at least part of the chassis is coarse-surfaced.

10. The electronic package according to claim 9,
wherein the coarse-surfaced part of the chassis is on a surface of the chassis facing outward.

11. The electronic package according to claim 1,
wherein at least part of the chassis has high-emissivity paint applied thereto.

12. The electronic package according to claim 11,
wherein the high-emissivity paint-applied part of the chassis is on a surface of the chassis facing outward.

13. An illuminating device comprising:
the electronic package according to claim 1; and
a light source which is mounted on the mounting surface of the mounting board.

14. The illuminating device according to claim 13,
wherein a reflective sheet covers the mounting surface, with a reflective surface of the reflective sheet facing outward and a reverse surface to the reflective surface facing the mounting surface, and
the reflective sheet has a perforation formed therein to expose only a light-exit region of the light source where the light source emits light.

15. A display device comprising:
an illuminating device according to claim 13; and
a display panel which receives light from the illuminating device.
